(19) United States
(12) Patent Application Publication
(10) Pub. No.: US 2024/0295611 A1
(43) Pub. Date: Sep. 5, 2024

(54) BATTERY MONITORING DEVICE, RESISTANCE VALUE DERIVATION METHOD, AND CELL VOLTAGE DERIVATION METHOD

(71) Applicant: LAPIS Technology Co., Ltd., Yokohama (JP)

(72) Inventor: Takayoshi FUJINO, Yokohama (JP)

(73) Assignee: LAPIS Technology Co., Ltd., Yokohama (JP)

(21) Appl. No.: 18/592,522

(22) Filed: Mar. 1, 2024

(30) Foreign Application Priority Data
Mar. 1, 2023 (JP) 2023-031330

(51) Int. Cl. G01R 31/389; G01R 31/3835; G01R 31/396; H01M 10/48

(52) U.S. Cl. CPC G01R 31/389; G01R 31/3835; G01R 31/396; H01M 10/482

(57) ABSTRACT

A battery monitoring device includes an analog-digital converter and a plurality of cell selection switches that selectively connect any of battery cells to the analog-digital converter. Each of the cell selection switches includes a first switch part, a second switch part, a third switch part, and a resistor element. The first switch part is provided on a conduction path leading from one of the battery cells to the analog-digital converter, brings the conduction path into a conductive state in an on-state of the first switch part, and brings the conduction path into a non-conductive state in an off-state of the first switch part. The second switch part switches on and off of the first switch part. The third switch part switches a magnitude of a current flowing into the first switch part when the first switch part is in the on-state. The resistor element is provided on the conduction path.

### CROSS-REFERENCE TO RELATED APPLICATION

This application claims the priority benefit of Japan application serial no. 2023-031330, filed on Mar. 1, 2023. The entirety of the above-mentioned patent application is hereby incorporated by reference herein and made a part of this specification.

### BACKGROUND

### Technical Field

The disclosed technique relates to a battery monitoring device, a resistance value derivation method, and a cell voltage derivation method.

### Related Art

The following techniques are known in relation to the technique of measuring the voltage of each battery cell in a battery pack composed of a plurality of battery cells connected in series.

Patent Document 1 (Japanese Patent Application Laid-Open No. 2013-223320) describes a battery charging device including: a battery pack in which a plurality of battery cells are connected in series; a transformer with a first winding and a plurality of second windings connected in parallel with the respective battery cells; a first switch connected in series with the first winding and connected in parallel with the battery pack; a plurality of second switches provided between wirings connecting the battery cells and the second windings; a measurement part that measures the voltage of each battery cell; a diode that flows a current of a constant direction from the second winding to the battery cell; and a control part that acquires a battery cell voltage measured by the measurement part, identifies the battery cell with the lowest voltage, brings the second switch corresponding to the identified battery cell into a connected state, brings the other second switches into a disconnected state, and performs control to repeat connection and disconnection of the first switch until the identified battery cell voltage is equal to or exceeds the average voltage of all the battery cells.

Patent Document 2 (Japanese Patent Application Laid-Open No. 2015-34750) describes a cell voltage monitoring device that measures the voltage of a stacked battery in which a plurality of battery cells are connected in series. The cell voltage monitoring device includes: a measurement circuit that measures the voltage of the stacked battery; a switch that has a plurality of input terminals to which the positive terminals of the plurality of battery cells are respectively connected and an output terminal to which the measurement circuit is connected, and switches the connection between the input terminal and the output terminal on a per-battery-cell basis; a control part that sequentially switches the connection of the switch to output the voltage of each battery cell to the measurement circuit at a predetermined cycle; and a monitoring part that monitors the power generation status of a predetermined battery cell based on the voltage of the predetermined battery cell measured by the measurement circuit at the predetermined cycle.

Patent Document 3 (Japanese Patent Application Laid-Open No. 2019-165583) describes a vehicle battery charging device including: a plurality of battery cell groups in which battery cells are connected in series; a total voltage detection part that detects a total voltage of the plurality of battery cell groups; a parallel connection switch that connects the plurality of battery cell groups in parallel; a series connection switch that connects the lowest-order cell in one battery cell group with the highest-order cell in another battery cell group among the plurality of battery cell groups; a switching control part that controls the parallel connection switch and the series connection switch to be off or on to switch the plurality of battery cell groups to parallel connection or series connection; and a welding determination part that determines welding of the series connection switch based on the total voltage during the period in which the series connection switch is controlled to the off-state by the switching control part.

A battery monitoring device that monitors the state of a battery cell of a battery pack composed of a plurality of battery cells connected in series has a function of measuring a two-terminal voltage (hereinafter referred to as a cell voltage) of each of the plurality of battery cells. To realize this function, the battery monitoring device includes an analog-digital converter and a plurality of cell selection switches that selectively connect any of the plurality of battery cells to the analog-digital converter. During cell voltage measurement, an operating current flows through the cell selection switch due to the operation of the cell selection switch. A low-pass filter composed of a resistor element and a capacitor is connected between the battery monitoring device and each battery cell to remove noise that is mixed in during cell voltage measurement. During cell voltage measurement, the operating current of the cell selection switch also flows through the resistor element constituting the low-pass filter, and a voltage drop occurs in the resistor element, so an error of a degree that cannot be ignored occurs in the measurement value of the cell voltage. For example, in the case where the resistance value of the resistor element constituting the low-pass filter is 1 kΩ and the operating current of the cell selection switch is 1 μA, an error of 1 mV occurs in the measurement value of the cell voltage. This error is not tolerable in vehicle-mounted battery monitoring devices developed in recent years. If it is possible to measure the resistance value of the resistor element constituting the low-pass filter, it will be possible to obtain the magnitude of the voltage drop in the resistor element during cell voltage measurement. By removing the component of the voltage drop in the resistor element from a digital value outputted from the analog-digital converter, an accurate cell voltage can be obtained. However, it is not easy to measure the resistance value of each resistor element provided corresponding to each of the plurality of battery cells.

### SUMMARY

A battery monitoring device according to an embodiment of the disclosed technique includes: an analog-digital converter; and a plurality of cell selection switches that selectively connect any of a plurality of battery cells to the analog-digital converter. Each of the cell selection switches includes a first switch part, a second switch part, a third switch part, and a resistor element. The first switch part is provided on a conduction path leading from one of the plurality of battery cells to the analog-digital converter, brings the conduction path into a conductive state in an on-state of the first switch part, and brings the conduction path into a non-conductive state in an off-state of the first switch part. The second switch part switches on and off of the first switch part. The third switch part switches a magnitude of a current flowing into the first switch part with the first switch part being in the on-state. The resistor element is provided on the conduction path.

A resistance value derivation method according to an embodiment of the disclosed technique derives, using the battery monitoring device described above, a resistance value of the resistor element. The resistance value derivation method includes the following. A first digital value is acquired, the first digital value being an output value of the analog-digital converter with the first switch part brought into the on-state and the third switch part brought into the off-state. A second digital value is acquired, the second digital value being the output value of the analog-digital converter with the first switch part brought into the on-state and the third switch part brought into the on-state. The resistance value of the resistor element is derived based on the first digital value and the second digital value.

A cell voltage derivation method according to an embodiment of the disclosed technique derives, based on a resistance value derived by the resistance value derivation method described above, a cell voltage of the battery cell. The cell voltage derivation method includes the following. A component of a voltage drop occurring in the resistor element at a time of acquiring the first digital value or the second digital value is derived based on the resistance value of the resistor element. A value obtained by removing the component of the voltage drop from the first digital value or the second digital value is derived as the cell voltage.

### BRIEF DESCRIPTION OF DRAWINGS

FIG. 1 is a diagram showing an example of a configuration of a battery monitoring device according to an embodiment of the disclosed technique.

FIG. 2 is a diagram showing an example of a configuration of a cell selection switch 20 according to an embodiment of the disclosed technique.

FIG. 3 is a flowchart showing an example of a flow of the process performed in a control part in the case where the control part functions as a resistance value derivation part according to an embodiment of the disclosed technique.

FIG. 4 is a flowchart showing an example of a flow of the process performed in the control part in the case where the control part functions as a cell voltage derivation part according to an embodiment of the disclosed technique.

### DESCRIPTION OF EMBODIMENTS

Embodiments of the disclosed technique enable measurement of a resistance value of a resistor element provided between a battery cell and a cell selection switch.

Hereinafter, an example of an embodiment of the disclosed technique will be described with reference to the drawings. In the drawings, the same or equivalent components and parts will be labeled with the same reference signs, and repeated descriptions will be omitted.

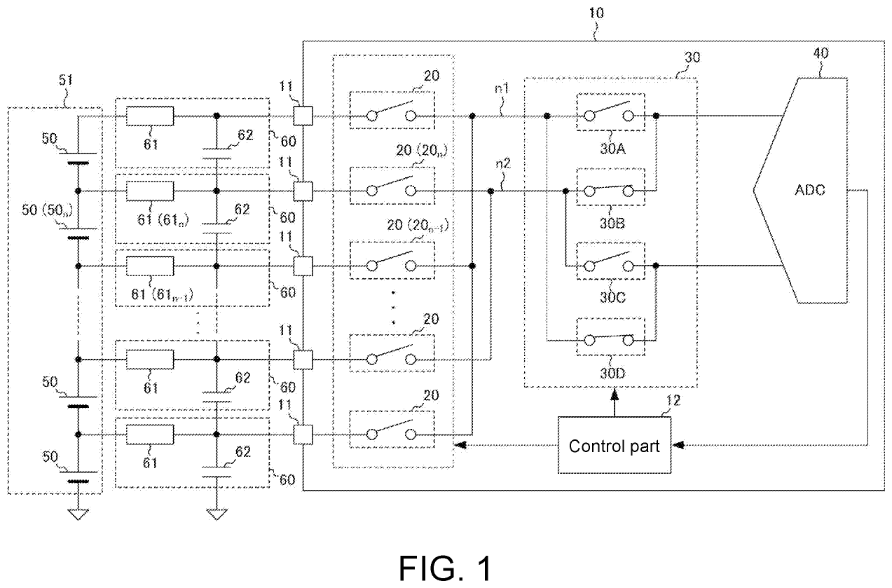

FIG. 1 is a diagram showing an example of a configuration of a battery monitoring device 10 according to an embodiment of the disclosed technique. The battery monitoring device 10 has a function of measuring a two-terminal voltage (hereinafter referred to as a cell voltage) of each battery cell 50 in a battery pack 51 composed of a plurality of battery cells 50 connected in series. The battery monitoring device 10 is composed of an integrated circuit provided on a semiconductor substrate. The battery monitoring device 10 includes a plurality of cell selection switches 20, a polarity inversion circuit 30, an analog-digital converter (ADC) 40, and a control part 12. The battery monitoring device 10 has a plurality of connection terminals 11 provided corresponding to the respective battery cells 50. The positive electrode of a corresponding battery cell 50 is connected to the connection terminal 11 via a low-pass filter 60.

The plurality of low-pass filters 60 are provided corresponding to the respective battery cells 50, and each include a resistor element 61 and a capacitor 62. One terminal of the resistor element 61 is connected to the positive electrode of the corresponding battery cell 50, and the other terminal of the resistor element 61 is connected to the corresponding connection terminal 11 and one terminal of the capacitor 62. The other terminal of the capacitor 62 is connected to the connection terminal 11 corresponding to the next-lower-order battery cell 50. One terminal of the capacitor 62 constituting the low-pass filter 60 corresponding to the lowest-order battery cell 50 is connected to the corresponding connection terminal 11, and the other terminal of this capacitor 62 is connected to ground.

The plurality of cell selection switches 20 are provided corresponding to the respective battery cells 50. The plurality of cell selection switches 20 selectively connect any of the plurality of battery cells 50 to the analog-digital converter 40. One terminal of the cell selection switch 20 is connected to the positive electrode of the corresponding battery cell 50 via the connection terminal 11 and the low-pass filter 60, and the other terminal of the cell selection switch 20 is connected to an integrated node n1 or n2. One of two cell selection switches 20 adjacent to each other is connected to one of the integrated nodes n1 and n2, and the other cell selection switch 20 is connected to the other of the integrated nodes n1 and n2.

The polarity inversion circuit 30 includes four switches 30A, 30B, 30C, and 30D composed of semiconductor elements such as transistors. One terminal of the switch 30A is connected to the integrated node n1 and the other terminal of the switch 30A is connected to the analog input of the analog-digital converter 40. One terminal of the switch 30B is connected to the integrated node n2 and the other terminal of the switch 30B is connected to the analog input of the analog-digital converter 40. One terminal of the switch 30C is connected to the integrated node n2 and the other terminal of the switch 30C is connected to the reference input of the analog-digital converter 40. One terminal of the switch 30D is connected to the integrated node n1 and the other terminal of the switch 30D is connected to the reference input of the analog-digital converter 40. The analog-digital converter 40 outputs a digital value corresponding to a difference between the voltage inputted into the analog input and the voltage inputted into the reference input.

The control part 12 controls on and off of the plurality of cell selection switches 20 and the switches 30A to 30D constituting the polarity inversion circuit 30. For example, in the case of measuring the cell voltage of a battery cell 501, the control part 12 controls cell selection switches 20ₙ and 20ₙ₋₁ to the on-state, controls the switches 30B and 30D of the polarity inversion circuit 30 to the on-state, and controls the switches 30A and 30C of the polarity inversion circuit 30 to the off-state. Accordingly, the positive electrode of the battery cell 50ₙ is connected to the analog input of the analog-digital converter 40, the negative electrode of the battery cell 50ₙ is connected to the reference input of the analog-digital converter 40, and a digital value corresponding to the cell voltage of the battery cell 50ₙ is outputted from the analog-digital converter 40.

The control part 12 derives the resistance value of the resistor element 61 based on the digital value outputted from the analog-digital converter 40. The control part 12 further derives the cell voltage based on the resistance value of the resistor element 61. The control part 12 is composed of a computer including a central processing unit (CPU) and a memory. The control part 12 is an example of a “resistance value derivation part” and a “cell voltage derivation part” in the disclosed technique.

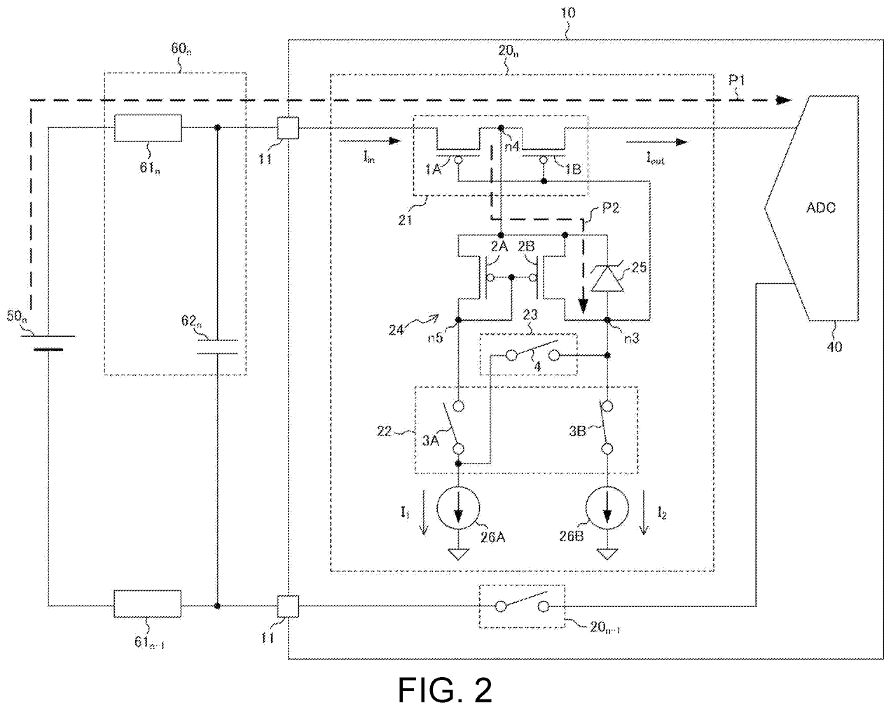

FIG. 2 is a diagram showing an example of the configuration of the cell selection switch 20ₙ. The configurations of each of the plurality of cell selection switches 20 are the same as each other. In FIG. 2, illustration of the polarity inversion circuit 30 is omitted. The cell selection switch 20ₙ includes a first switch part 21, a second switch part 22, a third switch part 23, a current mirror circuit 24, a Zener diode 25, a first current source 26A, and a second current source 26B.

The first switch part 21 is provided on a conduction path P1 leading from the positive electrode of the battery cell 50ₙ to the analog-digital converter 40. The first switch part 21 includes two P-channel metal-oxide-semiconductor field-effect transistors (MOSFETs) 1A and 1B connected in series. The MOSFETs 1A and 1B are power MOSFETs with a so-called double-diffused MOSFET (DMOS) configuration. The source of the MOSFET 1A is connected to the positive electrode of the corresponding battery cell 50ₙ via the connection terminal 11 and the resistor element 61, and the drain of the MOSFET 1A is connected to the source of the MOSFET 1B. The drain of the MOSFET 1B is connected to the analog input of the analog-digital converter 40. The gates of the MOSFETs 1A and 1B are each connected to a node n3 to which the anode of the Zener diode 25 is connected.

With both the MOSFETs 1A and 1B turning into the on-state, the first switch part 21 turns into the on-state, and the conduction path P1 turns into a conductive state. With the next-lower-order cell selection switch 20ₙ₋₁ also turning into the on-state, the positive electrode and the negative electrode of the battery cell 50ₙ are connected to the analog-digital converter 40, and a digital value corresponding to the cell voltage of the battery cell 50ₙ is outputted from the analog-digital converter 40. In contrast, with both the MOSFETs 1A and 1B turning into the off-state, the first switch part 21 turns into the off-state, and the conduction path P1 turns into a non-conductive state.

The current mirror circuit 24 includes two P-channel MOSFETs 2A and 2B. The sources of the MOSFETs 2A and 2B are each connected to a node n4, which is a connection point of the MOSFETs 1A and 1B. The gates of the MOSFETs 2A and 2B are each connected to the drain of the MOSFET 2A. The drain of the MOSFET 2A is connected to a node n5, and the drain of the MOSFET 2B is connected to the node n3. The anode of the Zener diode 25 is connected to the drain (node n3) of the MOSFET 2B, and the cathode of the Zener diode 25 is connected to the source (node n4) of the MOSFET 2B.

The second switch part 22 includes switches 3A and 3B composed of semiconductor elements such as transistors. One terminal of the switch 3A is connected to the node n5, and the other terminal of the switch 3A is connected to the first current source 26A. One terminal of the switch 3B is connected to the node n3, and the other terminal of the switch 3B is connected to the second current source 26B. The first current source 26A draws a constant current of a current value I₁. The second current source 26B draws a constant current of a current value I₂. In this embodiment, I₁=I₂. However, it may also be possible that I₁≠I₂.

The second switch part 22 switches on and off of the first switch part 21. The second switch part 22 includes switches 3A and 3B, which turn on and off complementarily according to control performed by the control part 12. With the switch 3A turning into the on-state and the switch 3B turning into the off-state, a current of the current value I₁ flows in the current mirror circuit 24. Accordingly, the gate-source voltages of the MOSFETs 1A and 1B constituting the first switch part 21 becomes approximately 0 V, and the MOSFETs 1A and 1B turn into the off-state (that is, the first switch part 21 turns into the off-state). In contrast, with the switch 3A turning into the off-state and the switch 3B turning into the on-state, the Zener diode 25 breaks down, a Zener current of the current value I₂ flows in the Zener diode 25, and a Zener voltage is generated across two terminals of the Zener diode 25. Accordingly, the gate-source of the MOSFETs 1A and 1B constituting the first switch part 21 is biased by the Zener voltage, and the MOSFETs 1A and 1B turn into the on-state (that is, the first switch part 21 turns into the on-state). The path leading from the node n4 to the node n3 via the Zener diode 25 is referred to as a branch path P2.

The third switch part 23 includes a switch 4 composed of a semiconductor element such as a transistor. One terminal of the switch 4 is connected to the node n3, and the other terminal of the switch 4 is connected to the high potential side of the first current source 26A. The third switch part 23 switches the magnitude of the current flowing into the first switch part 21 when the first switch part 21 is in the on-state. In the case where the first switch part 21 is in the on-state and the third switch part 23 is in the off-state, between the first current source 26A and the second current source 26B, only the second current source 26B is connected to the branch path P2. Thus, in the case where an outflow current Iₒᵤₜ flowing out from the first switch part 21 is zero, the current value of an inflow current Iᵢₙ flowing into the first switch part 21 becomes I₂ (=I₁). In contrast, in the case where the first switch part 21 is in the on-state and the third switch part 23 is in the on-state, both the first current source 26A and the second current source 26B are connected to the branch path P2. Thus, in the case where the outflow current Iₒᵤₜ flowing out from the first switch part 21 is zero, the current value of the inflow current Iᵢₙ flowing into the first switch part 21 becomes I₁+I₂ (=2I₂).

In the battery monitoring device 10, in the case of measuring the cell voltage of the battery cell 50, by bringing the first switch part 21 into the on-state, the conduction path P1 is brought into the conductive state, so the inflow current Iᵢₙ flows into the first switch part 21. The inflow current Iᵢₙ also flows through the resistor element 61 constituting the low-pass filter 60, and a voltage drop occurs in the resistor element 61, so an error of a degree that cannot be ignored occurs in the measurement value of the cell voltage. If it is possible to measure the resistance value of the resistor element 61, it will be possible to obtain the magnitude of the voltage drop in the resistor element 61 at the time of cell voltage measurement. By removing the component of the voltage drop in the resistor element 61 from the digital value outputted from the analog-digital converter 40, it is possible to obtain an accurate cell voltage. However, it is not easy to measure the resistance value of each resistor element 61 provided corresponding to each of the plurality of battery cells 50. Nonetheless, according to the battery monitoring device 10 in this embodiment, it is possible to easily derive the resistance value of the resistor element 61.

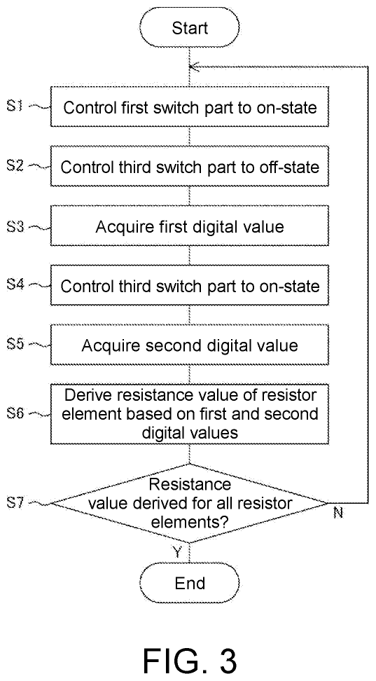

FIG. 3 is a flowchart showing an example of a flow of the process performed in the control part 12 in the case where the control part 12 functions as a resistance value derivation part deriving the resistance value of each resistor element 61. In the case of deriving the resistance value of a resistor element 61ₙ, in the next-lower-order cell selection switch 20ₙ₋₁, the first switch part 21 is maintained in the on-state, and the third switch part 23 is maintained in the off-state.

In step S1, in the cell selection switch 20ₙ, the control part 12 controls the first switch part 21 to the on-state by controlling the switch 3A of the second switch part 22 to the off-state and controlling the switch 3B to the on-state. In step S2, the control part 12 controls the third switch part 23 to the off-state.

Due to the switch control in steps S1 and S2, the positive electrode of the battery cell 50ₙ is connected to the analog input of the analog-digital converter 40, and the negative electrode of the battery cell 50ₙ is connected to the reference input of the analog-digital converter 40. At this time, in the case where the outflow current Iₒᵤₜ flowing out from the first switch part 21 is zero, the current value of the inflow current Iᵢₙ flowing into the first switch part 21 becomes I₂ (=I₁). The inflow current Iᵢₙ also flows through the resistor element 61ₙ constituting the low-pass filter 60ₙ, and a voltage drop occurs in the resistor element 61ₙ. A first digital value D1ₙ, which is the output value of the analog-digital converter 40 in the case of performing switch control in steps S1 and S2, is represented by the following equation (1). In equation (1), V_{cell_n} is the cell voltage of the battery cell 50ₙ, Rₙ is the resistance value of the resistor element 611, and Rₙ₋₁ is the resistance value of the resistor element 61ₙ₋₁. The first digital value D1ₙ corresponds to the cell voltage of the battery cell 50ₙ, but includes an error due to the voltage drop in the resistor elements 61ₙ and 61ₙ₋₁.

$$D {1}_{n} = {V}_{cell \_ n} - {R}_{n} \times {I}_{2} + {R}_{n - 1} \times {I}_{2} \qquad ( 1 )$$

In step S3, the control part 12 acquires the first digital value D1ₙ outputted from the analog-digital converter 40 and associates it with individual identification information of the battery cell 50ₙ to save to a memory (not shown).

In step S4, the control part 12 controls the third switch part 23 to the on-state while maintaining the first switch part 21 in the on-state. At this time, in the case where the outflow current Iₒᵤₜ flowing out from the first switch part 21 is zero, the current value of the inflow current Iᵢₙ flowing into the first switch part 21 becomes I₁+I₂ (=2I₂). The inflow current Iᵢₙ also flows through the resistor element 61ₙ constituting the low-pass filter 60ₙ, and a voltage drop occurs in the resistor element 61ₙ. A second digital value D2ₙ, which is the output value of the analog-digital converter 40 in the case of performing switch control in step S4, is represented by the following equation (2). The second digital value D2ₙ corresponds to the cell voltage of the battery cell 50ₙ, but includes an error due to the voltage drop in the resistor elements 61ₙ and 61ₙ₋₁.

$$D {2}_{n} = {V}_{cell \_ n} - {R}_{n} \times 2 {I}_{2} + {R}_{n - 1} \times {I}_{2} \qquad ( 2 )$$

In step S5, the control part 12 acquires the second digital value D2ₙ outputted from the analog-digital converter 40 and associates it with individual identification information of the battery cell 50ₙ to save to the memory (not shown).

In step S6, the control part 12 derives the resistance value Rₙ of the resistor element 61ₙ based on the first digital value D1ₙ acquired in step S3 and the second digital value D2ₙ acquired in step S5. Specifically, the control part 12 derives the resistance value Rₙ of the resistor element 61ₙ by calculating the following equation (3). The control part 12 associates the derived resistance value Rₙ with individual identification information of the battery cell 50ₙ to save to the memory (not shown).

$${R}_{n} = ( D {1}_{n} - D {2}_{n} ) / {I}_{2} \qquad ( 3 )$$

In step S7, the control part 12 determines whether derivation of the resistance value has been completed for all the resistor elements 61. The control part 12 repeats the process from step S1 to step S6 until derivation of the resistance value is completed for all the resistor elements 61.

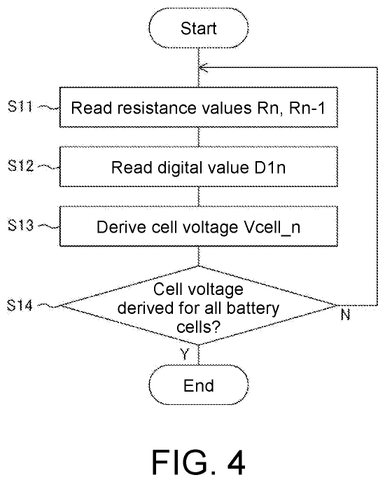

FIG. 4 is a flowchart showing an example of a flow of the process performed in the control part 12 in the case where the control part 12 functions as a cell voltage derivation part deriving the cell voltage of each battery cell 50.

In step S11, the control part 12 reads, from the memory (not shown), the resistance value Rₙ of the resistor element 61ₙ and the resistance value Rₙ₋₁ of the resistor element 61ₙ₋₁ derived in step S6 of the flowchart shown in FIG. 3.

In step S12, the control part 12 reads the first digital value D1ₙ used to derive the resistance value Rₙ from the memory (not shown).

In step S13, based on the resistance values Rₙ and Rₙ₋₁ of the resistor elements 61ₙ and 61ₙ₋₁, the control part 12 derives the component of the voltage drop occurring in the resistor elements 61ₙ and 61ₙ₋₁ at the time of acquiring the first digital value D1ₙ, and derives, as the cell voltage V_{cell_n}, a value obtained by removing the component of the voltage drop from the first digital value D1ₙ. Specifically, the control part 12 derives the cell voltage V_{cell_n} of the battery cell 50ₙ by performing calculation represented by following equation (4) based on the resistance values Rₙ and Rₙ₋₁ read in step S11 and the digital value D1ₙ read in step S12. The current value I₂ is assumed to be known.

$${V}_{cell \_ n} = D {1}_{n} + {R}_{n} \times {I}_{2} - {R}_{n - 1} \times {I}_{2} \qquad ( 4 )$$

In step S14, the control part 12 determines whether derivation of the cell voltage has been completed for all the battery cells 50. The control part 12 repeats the process from step S11 to step S13 until derivation of the cell voltage is completed for all the battery cells 50.

Although the above description exemplifies the case where the cell voltage V_{cell_n} of the battery cell 50ₙ is derived using the digital value D1ₙ, it is also possible to derive the cell voltage V_{cell_n} of the battery cell 50 using the digital value D2ₙ. That is, the control part 12 may also read the digital value D2ₙ in step S12, and derive the cell voltage V_{cell_n} of the battery cell 50ₙ by performing calculation represented by the following equation (5) based on the resistance values Rₙ and Rₙ₋₁ and the digital value D2ₙ in step S13.

$${V}_{cell \_ n} = D {2}_{n} + {R}_{n} \times 2 {I}_{2} - {R}_{n - 1} \times {I}_{2} \qquad ( 5 )$$

As described above, the battery monitoring device 10 according to the disclosed technique includes the analog-digital converter 40 and the plurality of cell selection switches 20 which selectively connect any of the plurality of battery cells 50 to the analog-digital converter 40. Each of the cell selection switches 20 includes: the first switch part 21 which is provided on the conduction path P1 leading from one of the plurality of battery cells 50 to the analog-digital converter 40, brings the conduction path P1 into the conductive state in the on-state of the first switch part 21, and brings the conduction path P1 into the non-conductive state in the off-state of the first switch part 21; the second switch part 22 which switches on and off of the first switch part 21; the third switch part 23 which switches the magnitude of the inflow current Iᵢₙ flowing into the first switch part 21 when the first switch part 21 is in the on-state; and the resistor element 61 provided on the conduction path P1. Furthermore, the battery monitoring device 10 includes: the first current source 26A connected to the branch path P2 branched from the conduction path P1 when the first switch part 21 is in the on-state; and the second current source 26B connected to the branch path P2 when the first switch part 21 and third switch part 23 are both in the on-state.

Furthermore, in the battery monitoring device 10, the control part 12 functions as a resistance value derivation part. The control part 12 functioning as the resistance value derivation part acquires the first digital value D1ₙ, which is the output value of the analog-digital converter 40 in the case where the first switch part 21 is in the on-state and the third switch part 23 is in the off-state, acquires the second digital value D2ₙ, which is the output value of the analog-digital converter 40 in the case where the first switch part 21 is in the on-state and the third switch part 23 is in the on-state, and derives the resistance value Rₙ of the resistor element 61ₙ based on the first digital value D1ₙ and the second digital value D2ₙ.

Furthermore, in the battery monitoring device 10, the control part 12 functions as a cell voltage derivation part. The control part 12 functioning as the cell voltage derivation part derives a component of a voltage drop occurring in the resistor elements 61ₙ and 61ₙ₋₁ when acquiring the first digital value D1ₙ or the second digital value D2ₙ, based on the resistance values Rₙ and Rₙ₋₁ of the resistor elements 61ₙ and 61ₙ₋₁, and derives, as the cell voltage V_{cell_n}, a value obtained by removing the component of the voltage drop from the first digital value D1ₙ or the second digital value D2ₙ.

According to the battery monitoring device 10 in the embodiment of the disclosed technique, it becomes possible to measure the resistance value of the resistor element 61. Moreover, based on the measured resistance value, it becomes possible to perform measurement of the cell voltage with high precision.

In this embodiment, as an example, it has been illustrated that the battery monitoring device 10 performs derivation of the resistance value of the resistor element 61 and derivation of the cell voltage. However, the derivation of the resistance value of the resistor element 61 and the derivation of the cell voltage may also be performed by an external device cooperating with the battery monitoring device 10. In that case, the battery monitoring device 10 supplies the first digital value D1ₙ and the second digital value D2ₙ to the external device.

Regarding the above embodiments, the following supplementary notes are further disclosed.

### (Supplementary Note 1)

A battery monitoring device including:
an analog-digital converter; and
a plurality of cell selection switches that selectively connect any of a plurality of battery cells to the analog-digital converter, where
each of the cell selection switches includes:
a first switch part that is provided on a conduction path leading from one of the plurality of battery cells to the analog-digital converter, brings the conduction path into a conductive state in an on-state of the first switch part, and brings the conduction path into a non-conductive state in an off-state of the first switch part;
a second switch part that switches on and off of the first switch part;
a third switch part that switches a magnitude of a current flowing into the first switch part with the first switch part being in the on-state; and
a resistor element that is provided on the conduction path.

### (Supplementary Note 2)

The battery monitoring device according to Supplementary note 1, further including:
a first current source that is connected to a branch path branched from the conduction path with the first switch part being in the on-state; and
a second current source that is connected to the branch path with the first switch part and the third switch part both being in the on-state.

### (Supplementary Note 3)

The battery monitoring device according to Supplementary note 1 or 2, further including:
a resistance value derivation part that derives a resistance value of the resistor element, where
the resistance value derivation part:
acquires a first digital value which is an output value of the analog-digital converter with the first switch part brought into the on-state and the third switch part brought into the off-state,
acquires a second digital value which is the output value of the analog-digital converter with the first switch part brought into the on-state and the third switch part brought into the on-state, and
derives the resistance value of the resistor element based on the first digital value and the second digital value.

### (Supplementary Note 4)

The battery monitoring device according to Supplementary note 3, further including:
a cell voltage derivation part that derives a cell voltage of the battery cell, where
the cell voltage derivation part:
derives a component of a voltage drop occurring in the resistor element at a time of acquiring the first digital value or the second digital value, based on the resistance value of the resistor element, and
derives, as the cell voltage, a value obtained by removing the component of the voltage drop from the first digital value or the second digital value.

### (Supplementary Note 5)

A resistance value derivation method that derives, using the battery monitoring device according to any one of Supplementary notes 1 to 4, a resistance value of the resistor element,
the resistance value derivation method including:
acquiring a first digital value which is an output value of the analog-digital converter with the first switch part brought into the on-state and the third switch part brought into the off-state;
acquiring a second digital value which is the output value of the analog-digital converter with the first switch part brought into the on-state and the third switch part brought into the on-state; and
deriving the resistance value of the resistor element based on the first digital value and the second digital value.

### (Supplementary Note 6)

A cell voltage derivation method that derives, based on a resistance value derived by the resistance value derivation method according to Supplementary note 5, a cell voltage of the battery cell,
the cell voltage derivation method including:
deriving a component of a voltage drop occurring in the resistor element at a time of acquiring the first digital value or the second digital value, based on the resistance value of the resistor element, and
deriving, as the cell voltage, a value obtained by removing the component of the voltage drop from the first digital value or the second digital value.

What is claimed is:

1. A battery monitoring device comprising:
an analog-digital converter; and
a plurality of cell selection switches that selectively connect any of a plurality of battery cells to the analog-digital converter, wherein
each of the cell selection switches comprises:
a first switch part that is provided on a conduction path leading from one of the plurality of battery cells to the analog-digital converter, brings the conduction path into a conductive state in an on-state of the first switch part, and brings the conduction path into a non-conductive state in an off-state of the first switch part;
a second switch part that switches on and off of the first switch part;
a third switch part that switches a magnitude of a current flowing into the first switch part with the first switch part being in the on-state; and
a resistor element that is provided on the conduction path.

2. The battery monitoring device according to claim 1, further comprising:
a first current source that is connected to a branch path branched from the conduction path with the first switch part being in the on-state; and
a second current source that is connected to the branch path with the first switch part and the third switch part both being in the on-state.

3. The battery monitoring device according to claim 1, further comprising:
a resistance value derivation part that derives a resistance value of the resistor element, wherein
the resistance value derivation part:
acquires a first digital value which is an output value of the analog-digital converter with the first switch part brought into the on-state and the third switch part brought into the off-state,
acquires a second digital value which is the output value of the analog-digital converter with the first switch part brought into the on-state and the third switch part brought into the on-state, and
derives the resistance value of the resistor element based on the first digital value and the second digital value.

4. The battery monitoring device according to claim 3, further comprising:
a cell voltage derivation part that derives a cell voltage of the battery cell, wherein
the cell voltage derivation part:
derives a component of a voltage drop occurring in the resistor element at a time of acquiring the first digital value or the second digital value, based on the resistance value of the resistor element, and
derives, as the cell voltage, a value obtained by removing the component of the voltage drop from the first digital value or the second digital value.

5. A resistance value derivation method that derives, using the battery monitoring device according to claim 1, a resistance value of the resistor element,
the resistance value derivation method comprising:
acquiring a first digital value which is an output value of the analog-digital converter with the first switch part brought into the on-state and the third switch part brought into the off-state;
acquiring a second digital value which is the output value of the analog-digital converter with the first switch part brought into the on-state and the third switch part brought into the on-state; and
deriving the resistance value of the resistor element based on the first digital value and the second digital value.

6. A cell voltage derivation method that derives, based on a resistance value derived by the resistance value derivation method according to claim 5, a cell voltage of the battery cell,
the cell voltage derivation method comprising:
deriving a component of a voltage drop occurring in the resistor element at a time of acquiring the first digital value or the second digital value, based on the resistance value of the resistor element, and
deriving, as the cell voltage, a value obtained by removing the component of the voltage drop from the first digital value or the second digital value.
